(19) United States
(12) Patent Application Publication
(10) Pub. No.: US 2006/0120034 A1
(43) Pub. Date: Jun. 8, 2006

(54) LCD structure with excellent heat dissipation efficiency

(76) Inventor: Ching-Hsien Huang, Chunghe City (TW)

Correspondence Address: LEONG C LEI, PMB # 1008, 1867 YGNACIO VALLEY ROAD, WALNUT CREEK, CA, 94598, US

(21) Appl. No.: 11/002,094

(22) Filed: Dec. 3, 2004

(51) Int. Cl. G06F 1/16; G06F 1/20; H05K 5/00

(52) U.S. Cl. 361/687

(57) ABSTRACT

An LCD structure with excellent heat dissipation efficiency is disclosed. The LCD structure has a display body comprising a front cover framed onto the front side of the display body; a rear cover framed onto the rear side of the display body, and the rear cover is mounted to the front cover to form a cavity to hold circuit board and electronic components, and the rear side surface of the rear cover has a through hole in communication with the cavity; and a rear panel, wherein a plurality of protruded pillars are formed between the edge of one side face of the rear panel and the through hole surrounding on the rear cover, the protruded pillar provide a distance for the rear panel to be mounted beyond the through hole of the rear cover so that a plurality of sideway dissipation holes are formed in between individual protruded pillars to the cavity.

### BACKGROUND OF THE INVENTION

(a) Technical Field of the Invention

The present invention relates to LCD structure, and in particular, to an LCD structure with excellent heat dissipation efficiency.

(b) Description of the Prior Art

Generally, LCD structure essentially has a display body having a rear side pivotally mounted to a base seat, allowing the display body on the base seat to be adjusted at appropriate angle. In order to allow the heat energy within the display body to be dissipated, a plurality of heat dissipation holes are provided to the housing of the display body. The dissipation holes should not affect the aesthetic appearance of the display, and therefore, the dissipation holes are positioned at the rear side and the sides that could not been seen. But, the heat of the display will flow through one direction to the rear and base of the display. However, it is a natural phenomenon that hot air rises and therefore the heat dissipation holes at the rear and at the bottom side will not provide efficient heat dissipation. As a result, the conventional LCD does not have long longevity. Accordingly, it is an object of the present to provide a LCD structure with excellent heat dissipation efficiency which mitigates the above drawbacks.

### SUMMARY OF THE INVENTION

Accordingly, it is an object of the present invention to provide a LCD structure with excellent heat dissipation efficiency having a display body hinged onto a seat body allowing the display body to be adjusted at an appropriate angle, wherein the display body includes a front cover framed onto the front side of the display body; a rear cover framed onto the rear side of the display body, and the rear cover is mounted to the front cover to form a cavity to hold circuit board and electronic components, and the rear side surface of the rear cover has a through hole in communication with the cavity; and a rear panel, wherein a plurality of protruded pillars are formed between the edge of one side face of the rear panel and the through hole surrounding on the rear cover, the protruded pillar provide a distance for the rear panel to be mounted beyond the through hole of the rear cover so that a plurality of sideway dissipation holes are formed in between individual protruded pillars to the cavity.

Still another object of the present invention is to provide a LCD structure with excellent heat dissipation efficiency having a display body hinged onto a seat body allowing the display body to be adjusted at an appropriate angle, wherein the seat body includes a securing plate being a horizontal plate body having one end pivotally mounted on the rear cover so that the display body swings at an appropriate angle on the seat body, a support plate being a plate body mounted below the securing plate and parallel to the securing plate; and a connection plate being an arch-shaped plate body having an upper edge connected to one side edge of the securing plate, and having a lower edge connected at one edge of the support plate such that the seat body formed into a U-shaped structure.

Yet another object of the present invention to provide a LCD structure with excellent heat dissipation efficiency, wherein a plurality of side way heat dissipation holes allows convection flow of air within the cavity and the hot air is dissipated at the side way direction of the LCD.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective exploded view of the present invention.

FIG. 2 is a perspective view of the present invention.

FIG. 3 is a sectional view of the present invention.

FIG. 4 shows a side view of heat dissipation in accordance with the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

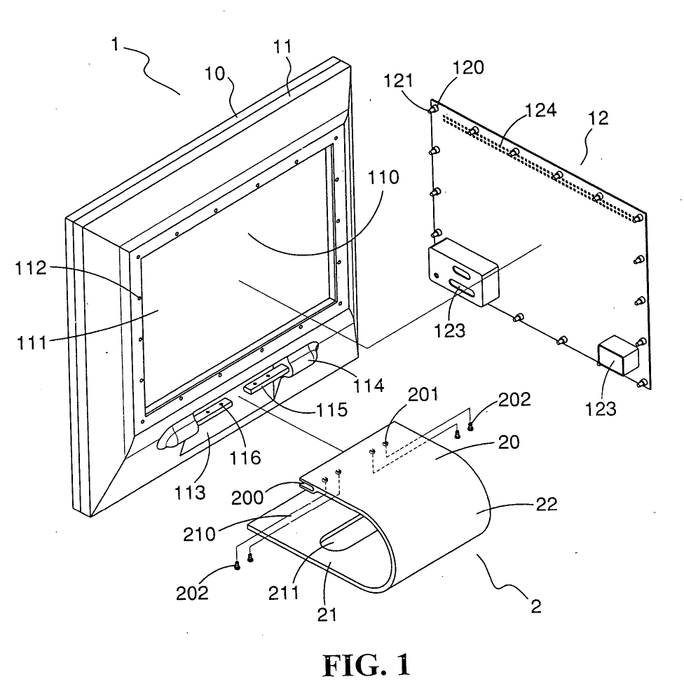

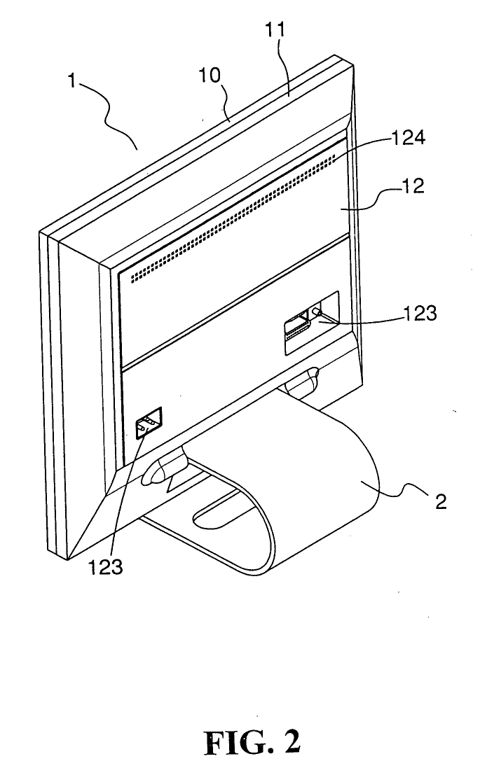

Referring to FIGS. 1 to 4, there is shown an LCD structure with excellent heat dissipation efficiency having a display body 1 hinged onto a seat body 2 at the bottom section at the side thereof, allowing the display body 1 to be adjusted at an appropriate angle. The display body 1 includes a front cover 10 which is a square frame body framed onto the edge of the front edge of the display body 1; a rear cover 11 which is a square frame body mounted onto the display body 1, and the rear cover 11 and the front cover 10 are correspondingly combined with each other to form a cavity 110 for holding IC boards and other electronic components. The rear side of the rear cover 11 at the center is a square shape through hole 111 which is in communication with the cavity 110. The surrounding of the through hole 111 is provided with a plurality of combination holes 112. The bottom section at the rear side of the rear cover 11 is a pivot slot 113. The two sides of the pivot slot 113 are respectively provided with a pivot seat 114 each. The pivot seats 114 have a chain 115 extended to the pivot slot 113. There is a plurality of screw holes 116 on the chain 115.

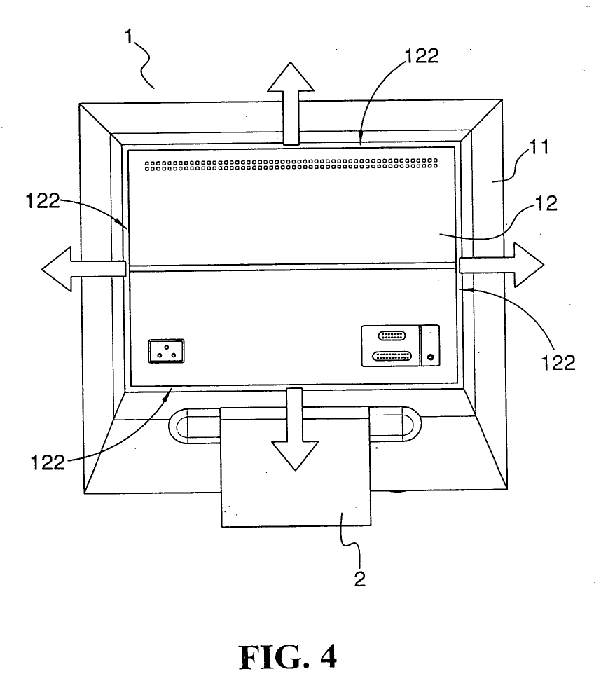

The display body 1 has a rear panel 12 mounted onto the through hole 111. The edge of the rear panel 12 has a plurality of protruded pillars 120 having combination pillars 121 with small diameter for mounting to the combination hole 112. The combination pillars 121 is protruded at the inner side of the combination hole 112 which is welded to the rear cover 10 to avoid dislocation. The protruded pillars 120 are a distance away above the through hole 111 of the rear cover 11 so that in between the protruded pillars 120, communication paths are formed to the sideway heat dissipation hole 122 of the cavity 110, as shown in FIG. 4. The rear panel 12 has a plurality of through holes 123 so that the signal cables or power source cable connector pass through the cavity 110, facilitating the connection of the signal or power source cable. The rear panel 12 is a plurality of heat dissipation holes 124.

The seat body 2 includes a securing plate 20 which is a horizontal plate body, having one end being a securing slot 200 for the engagement to the chain 115, and the bottom side of the securing slot 200 is in communication with the through hole 201. The through hole 201 for a screw 202 to pass through and lock at the screw hole 116 of the chain 115 so that the display body 1 is pivoted to the seat body 2.

The support plate 21 is secured at the bottom section of the securing plate 20 and the securing plate 20 is substantially parallel plate, and the securing plate 20 forms a forward facing slot 210. The support plate 21 has a slot 211 allowing a tool to be inserted to lock a screw 202 to the through hole 201.

The connection plate 22 is semi-arch shape plate body connected at one upper edge thereof to one edge of the securing plate 20. The bottom edge is connected to one side edge of the support plate 21 such that the seat body 2 is a U-shape plate body.

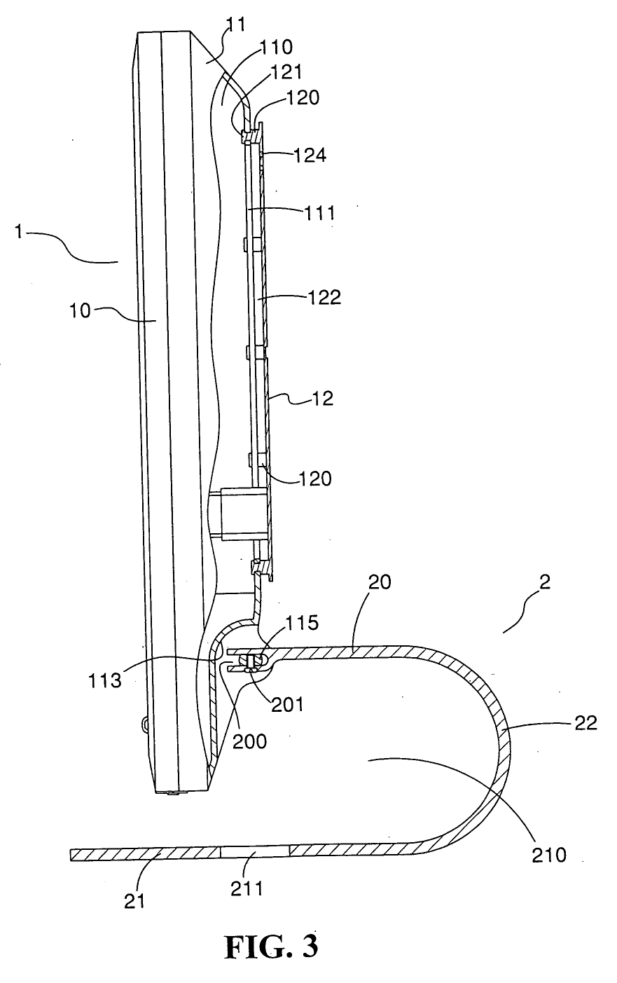

Referring to FIGS. 3 and 4, the protruded pillars 120 keep a distance from the through hole 111 of the rear cover 11, and the edges of the rear panel 12, between the rear cover and the rear panel 12, form into a plurality of sideway heat dissipation holes 122 in communication with the cavity 110 so that the heat of the display can be dissipated in four directions, and the sideway heat dissipation holes 122 can effectively enhance convection of air flow within the cavity 110. Accordingly, the LCD structure of the present invention provides excellent heat dissipation.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A LCD structure with excellent heat dissipation efficiency having a display body hinged onto a seat body allowing the display body to be adjusted at an appropriate angle, wherein the display body includes
a front cover framed onto the front side of the display body;
a rear cover framed onto the rear side of the display body, and the rear cover is mounted to the front cover to form a cavity to hold circuit board and electronic components, and the rear side surface of the rear cover has a through hole in communication with the cavity; and
a rear panel, wherein a plurality of protruded pillars are formed between the edge of one side face of the rear panel and the through hole surrounding on the rear cover, the protruded pillar provide a distance for the rear panel to be mounted beyond the through hole of the rear cover so that a plurality of sideway dissipation holes are formed in between individual protruded pillars to the cavity.

2. The LCD structure of claim 1, wherein around the surrounding of the through holes of the rear cover, a plurality of combination holes are provided, and the individual protruded pillar is installed with combination pillar mounted onto the combination hole having a smaller diameter as compared to that of the protruded pillar.

3. The LCD structure of claim 1, wherein the combination protruded pillar exposed at the inner side of the combination hole is fused on to the rear cover.

4. The LCD structure of claim 1, wherein beyond the side face of the rear cover is a pivotal slot, and the sides of the pivot slot are respectively provided with a pivot seat and the two pivot seats are individually mounted with a chain extended to the pivot slot, and the chain has a plurality of screw holes, and the seat body has a securing slot for the engagement of the chain and the bottom side of the securing slot has a plurality of through hole to the bottom section thereof, and the through hole is for screws to pass through.

5. The LCD structure of claim 1, wherein the rear panel is provided with a plurality of through holes for the passing through the connector within the cavity for the connection of the connection wire for signal or power source.

6. The LCD structure of claim 1, wherein the rear panel is provided with a plurality of heat dissipation holes through the rear panel arranged in rows.

7. The LCD structure of claim 1, wherein the seat body includes
a securing plate being a horizontal plate body having one end pivotally mounted on the rear cover so that the display body swings at an appropriate angle on the seat body,
a support plate being a plate body mounted below the securing plate and parallel to the securing plate; and
a connection plate being an arch-shaped plate body having an upper edge connected to one side edge of the securing plate, and having a lower edge connected at one edge of the support plate such that the seat body formed into a U-shaped structure.

8. The LCD structure of claim 7, wherein the bottom section of the side face of the rear is a pivot slot having a protruded pivot seat at each of the two sides of the slot, and the two pivot seat are provided with a chain extended to the pivot slot, and the chain has a plurality of screw holes, and the seat body has a securing slot for the engagement of the chain and the bottom side of the securing slot has a plurality of through hole to the bottom section thereof, and the through hole is for screws to pass through.

9. The LCD structure of claim 8, wherein the support plate has a slot hole allowing a tool to be inserted to tighten a screw to the through hole.
